(19) United States
(12) Patent Application Publication
(10) Pub. No.: US 2002/0070799 A1
(43) Pub. Date: Jun. 13, 2002

(54) Class D digital amplifier

(75) Inventors: Prosper Dahan, Kiryat Bialik (IL); Ron Kallus, Haifa (IL)

Correspondence Address: FITCH EVEN TABIN AND FLANNERY, 120 SOUTH LA SALLE STREET, SUITE 1600, CHICAGO, IL, 60603-3406, US

(73) Assignee: DIGITAL POWER SYSTEMS AG

(21) Appl. No.: 09/953,519

(22) Filed: Sep. 14, 2001

Related U.S. Application Data
(63) Continuation of application No. PCT/IL00/00187, filed on Mar. 27, 2000.

(30) Foreign Application Priority Data
Mar. 30, 1999 (IL) 129270

(51) Int. Cl. H03F 3/38

(52) U.S. Cl. 330/10

(57) ABSTRACT

A digital amplifier having a PWM modulator for modulating an analog input signal with a modulation signal so as to produce at an output thereof a pulse width modulated signal. A high power switch is responsively coupled to the output of the PWM modulator for switching between high level d.c. positive and negative voltages in accordance with a logic level of the pulse width modulated signal so as to produce a high power modulated switched signal, and a low pass filter is coupled to an output of the high power switch for filtering out the high frequency components of the signal. A feedback control loop is provided from the output of the high power switch to the analog input signal, and the modulation signal is of generally triangular shape.

### FIELD OF THE INVENTION

This invention relates to digital amplifiers.

### REFERENCES

In addition to the patents referenced in this specification, detailed reference is made to:

[1] “Pulse Edge Delay Error Correction (PEDEC)—A Novel Power Stage Error Correction Principle for Power Digital-Analog Conversion” by Karsten Nielsen, Proceedings of the 103^{rd} Convention of the Audio Engineering Society, September 1997.

[2] “A Review and Comparison of Pulse Width Modulation (PWM) Methods for Analog and Digital Input Switching Power Amplifiers” by Karsten Nielsen, Proceedings of the 102^{nd} Convention of the Audio Engineering Society, March 1997.

[3] “All Digital Power Amplifier Based on Pulse Width Modulation” by Karsten Nielsen, Proceedings of the 96^{th} Convention of the Audio Engineering Society, February 1994.

### BACKGROUND OF THE INVENTION

Class-D amplifiers process analog signals digitally using pulse-width modulation (PWM) techniques, thus resulting in increased efficiency. The PWM signals are applied to a power DMOS H-bridge, which provide high output current capability.

High-frequency square waves of constant amplitude, but varying width, are output from the modulator, When used to amplify audio, these pulses of varying widths contain the audio information. The output signal must be low-pass filtered to isolate the audio information from the high-frequency signal. Proper filtering assures the quality of the sound produced by the system.

FIG. 1 is a block diagram showing functionally the principal components of a Class D amplifier depicted generally as 10. Audio signals are fed to an input stage 11 whose output is modulated by a PWM modulator 12, which changes the analog input signal to a constant frequency, varying duty cycle, PWM signal. This seemingly complex operation is accomplished with a ramp generator set to a fixed frequency, 2501 kHz for example and comparator. The ramp generator typically produces a triangular waveform, which is connected to a comparator together with the analog input signal. The comparator's output switches each time the analog input signal and triangle waveform cross. The resulting output from the comparator is a 250 kHz PWM waveform, which contains the analog input signal information.

The resulting digital signal is fed to a PWM gain unit 13 that uses powerful and efficient DMOS transistors in an H-bridge configuration. The DMOS transistors, transfer power from the power supply to a low pass filter 14 using “packets of energy”, controlled by the PWM signal generated by the modulator 12. Transistors in Class-D amplifiers operate in the cutoff or saturation regions, similar to the operation of switch-mode power supplies. Operating the DMOS transistors in this way minimizes power losses commonly associated with transistors in linear power amplifiers. However, negligible losses associated with switching states and rDS(ON), this being the internal resistance of the DMOS while it is in the ON state, are unavoidable. Currently, the extent to which these losses are minimized is highly design-dependent and reflects in the overall cost of the amplifier. The low pass filter 14 which comprises an inductor and a capacitor requires careful design if much of the gain in efficiency is not to be lost in the filtering stage.

In spite of the improved efficiency of Class D amplifiers as compared with conventional analog power amplifiers, the use of these circuit topologies has not been as widespread as expected in the professional audio field for several reasons:

1. The direct dependence of the switching system's performance on the system's sampling frequency. This requires components which have not been readily available, obliging discrete solutions to be chosen, which are complicated to put into practice.

2. The poor performance of the low-pass filter, which reconstructs the amplified audio signal.

3. The difficulties involved in manufacturing reliable high-performance (low distortion) systems.

4. The difficulties involved in controlling the system's conducted and radiated emissions to avoid harmful effects on the system's components and interference with other equipment.

5. The cost of the system (decidedly more complicated from the point of view of design and manufacture) is only competitive for mid/high power set-ups, compared to its linear equivalent.

FIG. 2 is a block diagram showing functionally a conventional approach to improving performance based on error correction using feedback from the output of the low-pass filter to the input of the pulse modulator. Thus, there is shown a digital audio amplifier depicted generally as 20 comprising a pulse modulator 21, a power switch 22 and a demodulation filter 23. An error correction circuit 24 provides a feedback loop between the demodulation filter 23 and the pulse modulator 21. Such techniques are disclosed in both the scientific and patent literature.

For example, U.S. Pat. No. 5,410,592 (Wagner et al.) discloses a Class ‘D’ audio speaker amplifier circuit with state variable feedback control. An audio amplifier provides a power boost for telephone-sourced audio signals that drive one or more paging speakers. The state variable feedback network monitors voltage and current levels of an audio output filter to which the paging speakers are coupled, so as to adjust the operation of the amplifier circuit, as necessary, to compensate variations in the speaker loading of the audio output filter. The class D amplifier includes a pulse width modulator, which controls the switching of a power H-bridge-configured switching circuit. The switching circuit sources and sinks current with respect to the paging speaker load. The output of the power bridge switching circuit is a high energy square wave-type signal, which is filtered in a downstream audio filter to remove the switching transients and preserve the desired voice paging signal for application to the paging speakers. The state variable feedback network monitors variations in current flow and voltage at a plurality of circuit locations of the audio filter circuit and sums the monitored variations to produce an error signal, which is fed back to the input of the voice paging amplifier circuit and combined with the audio input signal.

U.S. Pat. No. 4,178,556 (Attwood; Brian E.) discloses a Class D amplifier system comprising a pulse width modulator for pulse width modulating with an audio signal a carrier signal having a frequency higher than that of the audio signal. An output switching amplifier is connected to the modulator, and a low-pass filter is connected to the output amplifier to supply a demodulated audio signal to a load. A trap circuit resonant at a carrier signal frequency is provided in the low-pass filter to permit part of an output signal from the trap circuit which is free from a carrier signal component to be negative-fed back to the pulse width modulator.

U.S. Pat. No. 4,059,807 (Hamada) assigned to Sony Corporation discloses a pulse width modulated amplifier. A pulse width modulation circuit comprises a mixer for combining an input audio signal with a feedback signal and for developing a difference signal to feed to an integration circuit. The integration circuit is coupled to a pulse width modulator, which has a saw-tooth carrier input for modulating the input audio signal. The resulting pulse modulated signal is then fed to a pulse amplifier and a low-pass filter and finally to a load. The output of the low-pass filter is coupled back to the mixer.

U.S. Pat. No. 4,021,745 (Suzuki et al.) also assigned to Sony Corporation discloses a pulse width modulated signal amplifier having a first input terminal supplied with a rectangular wave signal as a carrier, and a second input terminal supplied with a modulating signal, such as an audio signal. Both the rectangular wave signal and the modulating signal are fed to an integrator, whose output is fed to a high gain amplifier. A low pass filter coupled to the high gain amplifier produces a demodulated signal corresponding to the modulating signal and which is supplied to an output terminal. A negative feedback circuit is connected between the output of the high gain amplifier and the input of the integrator.

The rectangular wave signal is integrated by the integrator so as to produce a saw tooth signal which is shifted in phase by 90° with respect to the rectangular wave signal. Likewise, because the modulating signal is also fed to the high gain amplifier via the integrator, it too is phase shifted by 90°. Thus, so far as the two signals, which are fed to the high gain amplifier, are concerned, they are equivalent to feeding a regular saw-tooth signal together with the modulating signal as is more commonly done in the art. However, because they are phase shifted by 90° in the integrator, when the pulse width modulated signal derived from the high gain amplifier is negatively fed back to the input of the integrator, the effective phase shift is 180° thus theoretically ensuring that the negative feedback is stable and that the high gain amplifier will not oscillate.

In practice, on simulating the circuit disclosed by Suzuki et al. it is far from clear that the configuration disclosed therein achieves the objective of improved stability. Certainly, from a consideration of the circuit topology, it is apparent that Suzuki et al apply their feedback to the integrator input, i.e. the very point in the circuit which they want to stabilize. As a result, the circuit is prone to instability problems, which must be corrected by external circuitry, thus increasing the amplifier's complexity and cost.

U.S. Pat. No. 4,472,687 (Kashiwagi et al.) discloses an audio power amplifier for supplying electric power to a load by switching of power supply voltage. To this end, DC power supply is coupled to a load through a switching element, a smoothing circuit, and an output amplifying element receives an input signal voltage to be amplified A voltage detecting circuit is provided which compares a feedback voltage proportional to an output voltage of the smoothing circuit, with the input signal voltage to switch the switching element, thereby varying both the power supply voltage of output amplifying element and the load output voltage in accordance with the input signal voltage. As the output voltage of the smoothing circuit is compared with the input signal voltage, the delay of the change of the power supply voltage of the output amplifying element relative to the load output voltage can be reduced, and the generation of distortion and the lowering of efficiency can be suppressed.

U.S. Pat. No. 4,504,793 (Yokoyama) discloses an audio Class “D” amplifier employing a PWM modulator for controlling a power switch in a classic Class “D” configuration. The PWM modulator uses a threshold comparator to compare a triangular modulation signal with an integrated output feedback signal. When the feedback signal crosses the triangular modulation signal, the comparator changes state and feeds a control signal to a high power amplifier for producing at its output a high amplitude positive or negative voltage level, which is filtered by a low pass filter in known manner. Yokoyama is directed to a pulse-width modulation circuit wherein non-linear distortion of the triangular modulation signal has no adverse effect upon the modulated output.

A drawback of such an arrangement is that, owing to the high gain of the threshold comparator, its output is subject to jitter thus altering the ratio between the positive and negative portions of the amplified output pulse waveform and thus changing the instantaneous amplitude of the filtered audio output. The jitter manifests itself as an effective variation in the crossover of the input signal and the integrated output feedback signal, whereby even if the modulating signal is compared with an unvarying signal, the crossover of the threshold comparator is subject to variation. As a result, the effective ratio between the positive and negative output pulses from the high power switch varies and the average output voltage, after low pass filtering, is subject to distortion.

Moreover, as is also classic Class “D” configuration, the integrated output signal is compared with the input signal. U.S. Pat. No. 4,504,793 actually employs two stages of comparison. A first stage comparator compares the input signal with the fed-back output signal and the output of this comparator serves as the reference for a second stage comparator, which compares the triangular modulation signal with the integrated output signal. It is thus to be noted that the PWM modulator proposed in U.S. Pat. No. 4,504,793 uses two comparator stages connected in series for reducing the effect of distortions in the triangular modulation signal.

Many of the techniques used in Class D amplifier are detailed in a series of papers [1], [2] and [3] authored by Karsten Nielsen and presented at the Audio Engineering Society. In particular, reference [1] elaborates on the source of distortions in conventional Class D amplifiers. It will be recalled, in this regard, that the core technology of Class D amplifiers is not by any means new. The above-referenced patents all attempt to improve the distortions associated with known Class D amplifiers and, as explained by Nielsen [1], the intense efforts notwithstanding, prior art solutions are not entirely successful. The solution proposed by Nielsen [1] is based on a PEDEC controller having a complex transfer function and being connected between the digital modulator and the demodulator as shown in FIGS. 8, 9 and 28 of his paper to which reference should be made for a detailed review.

As further noted by Nielsen [3], many different PWM techniques are known using modulating signals of various shapes. In particular, reference is made to FIG. 6 in this paper showing different examples of PWM. FIG. 2 in the same paper shows that theoretically the efficiency of a Class D amplifier is 100%, although in practice it is somewhat less for the reasons noted above.

It will noted that the manner in which feedback is typically achieved in prior art circuit topologies relies on subtracting the fed-back signal from the input analog signal which is itself fed to the inverting input of the PWM modulator. Furthermore, prior art topologies commonly require that the feedback correction be applied to the demodulated output signal produced at the output of the filter. That is to say, feedback control is usually based on the filtered signal, representing the actual amplified audio output

It is contended by Tripath Technology, Inc. that feedback techniques on their own do not provide a complete reduction in distortion. In their Web page http://www.tripath.com/ they state that the output transistors, based on fast operation MOSFETs, can never be perfectly matched. As a result there is an inevitable delay between one transistor switching off and its pair switching on, giving rise to some distortion. They further contend that the switching of the output transistors causes “ground bounce” which itself introduces noise, and that the low-pass filter on its own cannot totally remove the PWM waveform.

Tripath Technology, Inc. address these issues by employing signal processing techniques wherein mathematical algorithms are used to effect the modulation necessary for switching the output transistors.

### SUMMARY OF THE INVENTION

It is an object of the invention to provide a digital amplifier that addresses the drawbacks of hitherto-proposed circuits without requiring complex correction, either by way of hardware circuitry or software processing.

The invention provides a digital amplifier comprising:

a PWM modulator for modulating an analog input signal with a modulation signal so as to produce at an output thereof a pulse width modulated signal,

a high power switch responsively coupled to the output of the PWM modulator for switching between high level dc. Positive and Negative voltages in accordance with a logic level of the pulse width modulated signal so as to produce a high power modulated switched signal,

a low pass filter coupled to an output of the high power switch for filtering out the high frequency components of the signal;

CHARACTERIZED IN THAT:

the PWM modulator comprises an amplifier chain including at least two fast, low-gain amplifiers connected in cascade,

an integrator is provided for integrating the analog input signal and producing an integrated analog signal, and

an adder is coupled to an output of the integrator for adding the modulation signal to the integrated analog signal.

Such a circuit topology differs from the prior art in the provision of an amplifier chain including at least two fast, low-gain amplifiers connected in cascade. It has been found that this removes or at least reduces jittering of the device, the source of which is inherent to the nature of amplifiers. This, in turn, gives rise to a time shift of the digital pulse output by the PWM modulator and this gives rise to errors in the amplified signal.

Preferably, the modulation signal is of generally triangular shape and a feedback control loop is applied from the output of the high power switch to the analog input signal. It is true that U.S. Pat. No. 4,021,745 also teaches the application of negative feedback from the output of the high power switch to the analog input signal. However, the modulation signal, which is actually mixed with the analog input signal, prior to integration, is a square wave signal. Only when both signals together are integrated, is the familiar saw-tooth waveform generated.

Likewise, Nielsen [3] discloses the application of negative feedback from the output of the high power switch. However, it appears that the output is fed back to the output of the modulator, whilst in the invention it is fed back to the analog input signal prior to modulation.

When a digital amplifier includes both features of the invention, i.e. cascaded amplifiers as well as a feedback control loop from the output of the high power switch to the analog input signal, the improvement in the amplifier output is striking.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1 is a block diagram showing functionally the principal components of a prior art Class D amplifier,

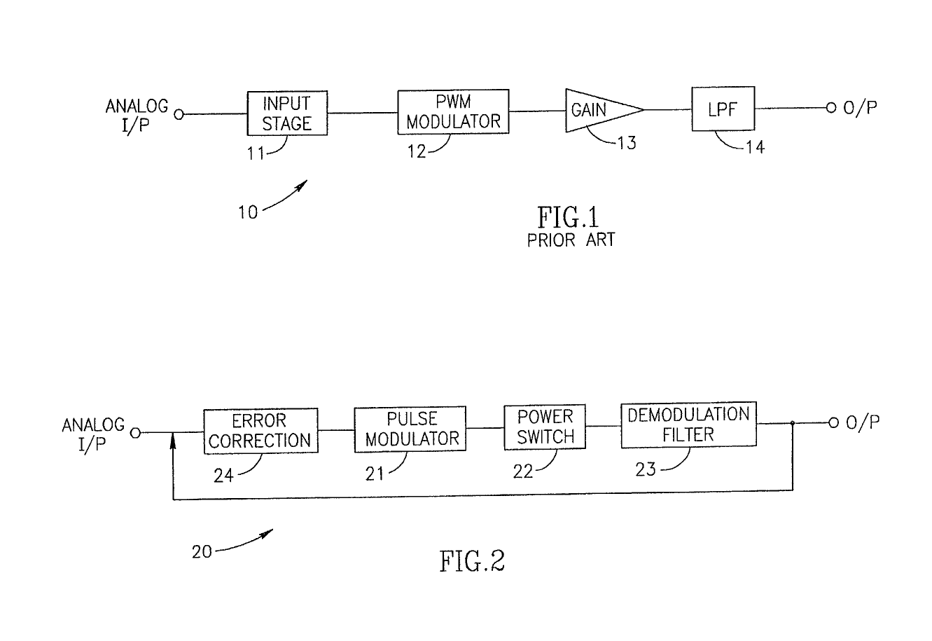

FIG. 2 is a block diagram showing functionally a conventional feedback approach to improving performance of the circuit shown in FIG. 1;

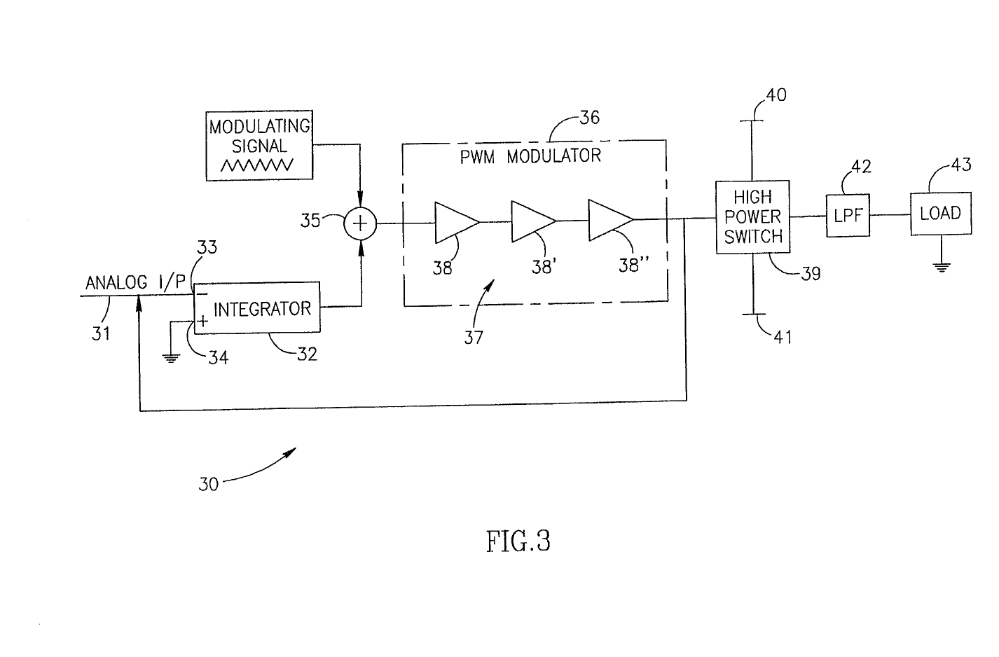

FIG. 3 is a schematic diagram showing functionally a digital amplifier according to the invention; and

FIGS. 4 and 5 show voltage waveforms of critical points in the Class D amplifier shown schematically in FIG. 3.

### DETAILED DESCRIPTION OF A PREFERRED EMBODIMENT

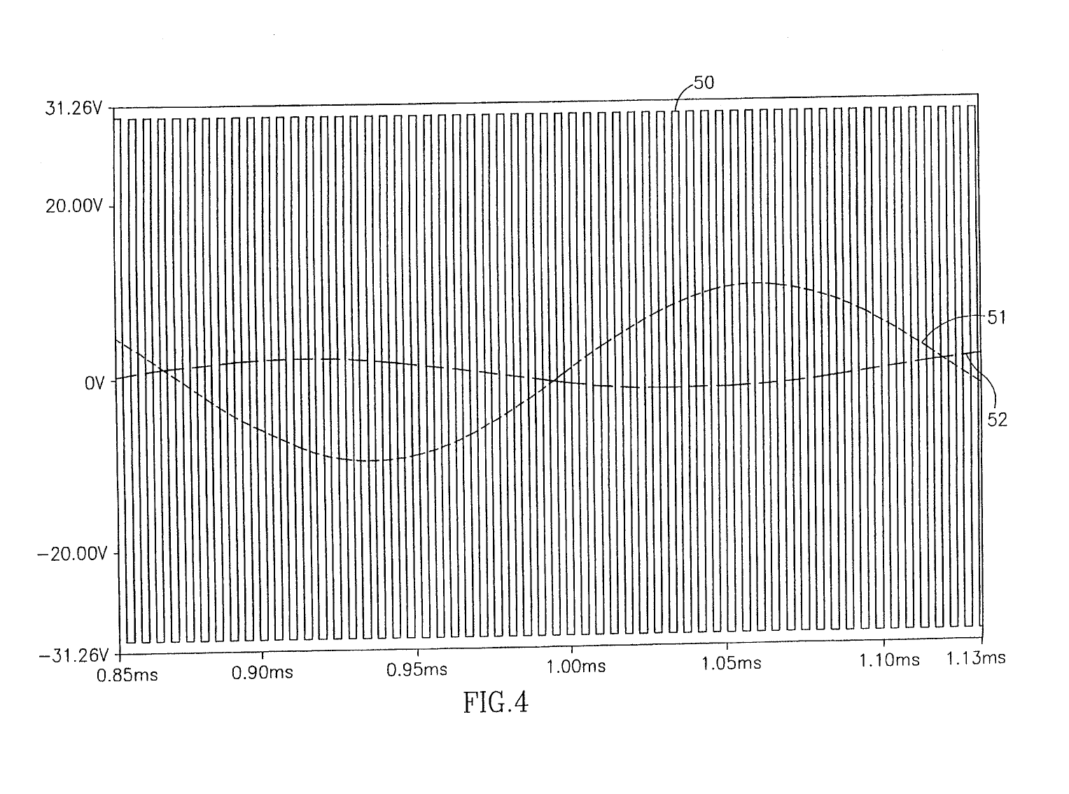

FIG. 3 shows functionally a Class D digital amplifier depicted generally as 30 wherein an audio input signal 31 is fed through an integrator 32 having an inverting input 33 and a grounded non-inverting input 34, and added to a saw tooth modulation signal via an adder 35. The output of the added is fed through a PWM modulator 36 comprising an amplifier chain 37 including at least two fast, low-gain amplifiers 38, 38′, 38″ connected in cascade. In a practical embodiment, three low-gain amplifiers stages were used in the PWM modulator 36 each having a high speed. The output of the PWM modulator 36 is fed to a high power switch 39 connected to positive and negative d.c. supply rails 40 and 41, respectively. The output of the high power switch 39 is connected to a Low Pass filter 42 across whose output a load 43 is connected.

The output of the high power switch 39 is fed back to the inverting input 33 of the integrator 32 so as to act on the audio input signal 31 before modulation by the saw tooth modulation signal. This is in marked contrast to what is done in U.S. Pat. No. 4,021,745 (Suzuki et al.) where the feedback signal is fed to the already modulated input signal.

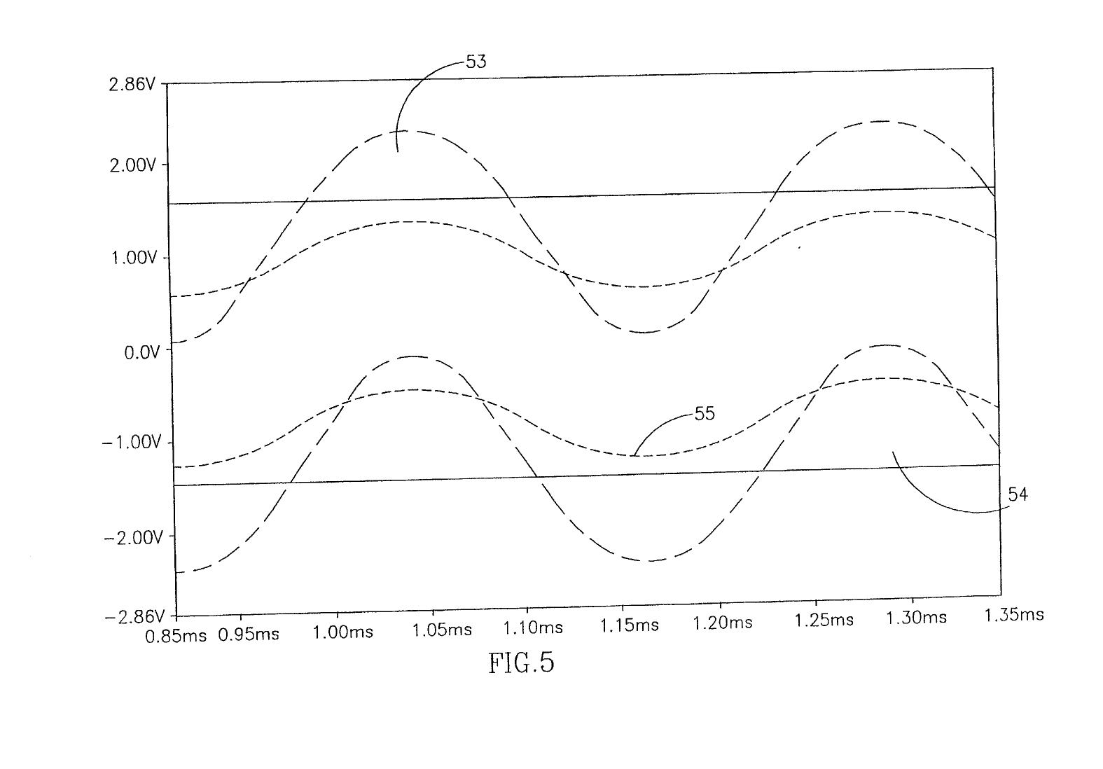

Figs 4 and 5 show waveforms at various critical junctions in the circuit shown in FIG. 3 derived by computer simulation of the circuit. Thus, the waveform 50 corresponds to the digital output voltage appearing at the output of the high power switch 39. It is seen that the digital output voltage is a square wave pulse train having an amplitude between ±31 volts and having an approximate frequency of 240 KHz. Waveform 51 represents the audio input signal 31 (without feedback) shown as a sinusoidal periodic signal having an amplitude between ±10 volts and having an approximate frequency of 4 KHz. Waveform 52 represents the audio output signal appearing at the output of the low pass filter 42 as a sinusoidal periodic signal having an amplitude between ±1 volt and having an approximate frequency of 4 KHz.

Waveform 53 shown in contour represents the audio input signal 31 with feedback shown as a sinusoidal periodic signal modulated by the saw tooth modulation signal shown as waveform 54 in contour. Waveform 55 also shown in contour represents the modulated input to the PWM modulator 36 this being similar in shape to the audio input signal 31 with feedback represented by the waveform 54.

1. A digital amplifier comprising:
a PWM modulator for modulating an analog input signal with a modulation signal of generally triangular shape so as to produce at an output thereof a pulse width modulated signal,
a high power switch responsively coupled to the output of the PWM modulator for switching between high level d.c. positive and negative voltages in accordance with a logic level of the pulse width modulated signal so as to produce a high power modulated switched signal, and
a low pass filter coupled to an output of the high power switch for filtering out the high frequency components of the signal;
CHARACTERIZED IN THAT:
the PWM modulator comprises an amplifier chain including at least two fast, low-gain amplifiers connected in cascade, an integrator is provided for integrating the analog input signal and producing an integrated analog signal, and
an adder is coupled to an output of the integrator for adding the modulation signal to the integrated analog signal.

2. The digital amplifier according to claim 1, further including a feedback control loop from the output of the high power switch to the analog input signal.

3. The digital amplifier according to claim 2, wherein the feedback control loop is applied to a negative input of the integrator.

4. The digital amplifier according to claim 1, wherein the modulation signal is of generally triangular shape.

5. The digital amplifier according to claim 2, wherein the modulation signal is of generally triangular shape.

6. The digital amplifier according to claim 3, wherein the modulation signal is of generally triangular shape.

7. A digital amplifier comprising:
a PWM modulator for modulating an analog input signal with a modulation signal of generally triangular shape so as to produce at an output thereof a pulse width modulated signal,
a high power switch responsively coupled to the output of the PWM modulator for switching between high level d.c. positive and negative voltages in accordance with a logic level of the pulse width modulated signal so as to produce a high power modulated switched signal, and
a low pass filter coupled to an output of the high power switch for filtering out the high frequency components of the signal;
CHARACTERIZED IN THAT:
a feedback control loop is provided from the output of the high power switch to the analog input signal,
the modulation signal is of generally triangular shape,
an integrator is providing for integrating the analog input signal and producing an integrated analog signal, and
an adder is coupled to an output of the integrator for adding the modulation signal to the integrated analog signal.

8. The digital amplifier according to claim 7, wherein the feedback control loop is applied to a negative input of the integrator.
